(19) United States
(12) Patent Application Publication
(10) Pub. No.: US 2013/0206469 A1
(43) Pub. Date: Aug. 15, 2013

(54) EMI GASKET ASSEMBLY FOR ANGLED CAGE APPLICATION AND SHIELDING CAGE INCORPORATING SAME

(71) Applicants: Danny P. Cantrell, Conway, AR (US); Kenneth F. Janota, Conway, AR (US)

(72) Inventors: Danny P. Cantrell, Conway, AR (US); Kenneth F. Janota, Conway, AR (US)

(73) Assignee: MOLEX INCORPORATED, Lisle, IL (US)

(21) Appl. No.: 13/695,961

(22) PCT Filed: May 3, 2011
(86) PCT No.: PCT/US11/34963

§ 371 Date: Dec. 10, 2012

Related U.S. Application Data
(60) Provisional application No. 61/330,660, filed on May 3, 2010.

(51) Int. Cl. H05K 9/00

(52) U.S. Cl. CPC H05K 9/0015
USPC 174/358

(57) ABSTRACT

An EMI gasket assembly as used in angled shielding cage applications and includes a gasket frame with an opening that receives the front end of the cage therein. The gasket frame has guides disposed on one side of it that contact the cage and orient it at an angle to the gasket frame. The gasket frame further includes at least a pair of clips that retain a conductive, compressible in place around the frame opening.

### REFERENCES TO RELATED APPLICATIONS

The Present Disclosure claims priority to prior-filed U.S. Provisional Patent Application No. 61/330,660, entitled “EMI Gasket Assembly For Angled Cage applications And Shielding Cage Incorporating Same,” filed on 3 May 2010 with the UNITED STATES PATENT AND TRADEMARK OFFICE. The contents of the aforementioned patent application is fully incorporated in its entirety herein.

### BACKGROUND OF THE PRESENT DISCLOSURE

The Present Disclosure relates generally to devices used to block electromagnetic interference (“EMI”) in association with electronic devices and more particularly to an angled EMI gasket assembly for use with such devices.

EMI is a problem in the electronics industry. EMI becomes more problematic at high operational data transfer speeds in environments such as routers and servers. Many electronic devices, such as servers and the like are interconnected to other devices by way of plug connectors which are inserted into exterior openings in the devices. A device may contain one or more internal board mounted connectors that are matable with a circuit card, commonly referred to as an edge card. The internal connectors are housed within metal shielding cages that open along a face plate, or bezel of the device in order to receive mating plug connectors that connect with the device.

A problem arises in that most connectors and their shielding cages are mounted perpendicular to the face plate so that when plug connectors are inserted (in a “straight-on” manner) into the cages to mate with the internal connectors, the cables extend straight out from the device. Typically, the device will include an external cover and these plug connector cables must be bent about 90 degrees to fit within the cover. With internal connectors of the straight-on style, the cover must be spaced far away from the face panel in order to accommodate the plug connector and thus increases the overall size of the device.

It is desirable to reduce this cover space, and one way of doing so is to mount the internal connectors and their associated shielding cages at an angle to the face plate. This reduces the amount of space required for the cover and reduces the overall size of the device because the plug connector is angled and does not protrude in its entire longitudinal extent away from the face plate. However, this arrangement typically requires the use of a custom, stepped printed circuit board and either a die-cast frame or custom face place or bezel adapter. These custom elements increase the overall cost of the device. A need therefore exists for an angled frame assembly that includes an EMI gasket for effective EMI shielding at the bezel. The Present Disclosure is directed to an improved angled EMI gasket assembly that overcomes the above shortcomings

### SUMMARY OF THE PRESENT DISCLOSURE

The Present Disclosure is therefore directed to improved EMI gasket assemblies that are suitable for angled applications and which are inexpensive to implement.

In one aspect, an EMI gasket assembly is provided that includes a frame that has an opening formed therein to receive a portion of the shielding cage therein at an angle thereto, and one or more alignment guides that orient the shielding cage and that also contact the cage. A flexible conductive gasket is provided and engages gasket-retaining clips on the gasket frame to hold the gasket in place between the frame and a face plate, or bezel, of the device in which the gasket assembly is used.

In another aspect, the alignment guides and gasket-retaining clips are formed with and as part of the frame in order to facilitate the manufacturing of the gasket assembly. As such, the frame may take a rectangular shape with a central opening and the guides and gasket-retaining clips are formed by the metal that normally would be stamped out of the frame in the central opening, with the alignment guides having edges that contact the shielding cage and orient it at a desired angle.

In yet another aspect, the gasket frame may incorporate multiple extents of spring fingers that are formed integrally as part of the frame. The fingers can be bent both rearwardly and forwardly of the frame to form, in essence, a combination alignment guide-gasket retaining clip. Utilizing the fingers as the structure from which to form the guide and clip, the fingers can be easily bent in opposing directions so as to contact both the shielding cage and the gasket.

These aspects and the advantages of the gasket assemblies are made possible by the structure thereof. In one embodiment, the EMI gasket assembly includes a four-sided frame, preferably a rectangular one with a central opening. The frame is sized so that it fits over and preferably contacts four opposing sides of the shielding cage to provide an effective ground path. The frame includes a plurality of first and second members that respectively serve to orient the shielding cage and retain a flexible gasket in place on it.

The first members are considered as alignment guides and at least one of them extends generally rearwardly from the gasket frame at a preselected angle that preferably matches the angle at which the shielding cage sits on the circuit board. These first members act as guides to orient either the gasket frame on the shielding cage, or the shielding cage within the gasket frame. In one embodiment, the alignment guides may be formed integrally with the gasket frame. Two of these alignment guides are preferably arranged parallel to each other at the selected angle and a third alignment guide may be used and positioned between the first two alignment guides. This third alignment guide preferably contacts the top of the shielding cage and includes an angled edge which may be used to align a side edge of the cage with the third and the other two alignment guides. All three alignment guides make contact with the cage and provide attachment surfaces that can be welded, or otherwise attached, to the shielding cage.

The gasket frame second members are disposed on the front of the gasket frame, preferably on opposite sides of the frame opening and extend forwardly therefrom. These second members serve as gasket-retaining clips around which a flexible, conductive gasket extends. The gasket-retaining clips keep the gasket in place and prevent it from coming off of the frame during assembly of the gasket frame onto the shielding cage. In one embodiment of the Present Disclosure, one of these clips is separately formed from an angled piece of metal and is attached to the front face of the gasket frame along one side of the frame opening. The other clip extends forwardly along an opposing side of the frame opening. Ideally, the shielding cage contacts each of these clips in order to provide electrical grounding contact to the shielding cage. The conductive gasket extends over and around the frame opening so that it confronts and contacts the rear face of the faceplate or bezel, when the device is assembled. The clips are structured so that they extend out forwardly from the frame, and preferably, generally perpendicular to the front face of the bezel or to the sides/walls of the gasket frame. In this regard, the clips and the frame front face provide a pair of L-shaped gasket retention members, which reliably hold the conductive gasket in place so that it may be compressed between the gasket frame and the bezel. The gasket-retaining clips also provide continuous electrical grounding contact between the shielding cage and the gasket and gasket frame.

In another embodiment of the gasket assembly, both of the alignment guides and the gasket retaining clips are formed integrally with the frame along edges of the opening thereof. In this embodiment, a series of elongated members, such as fingers, are formed along one of the sides of gasket frame opening. One of the fingers extends rearwardly to form a alignment guide while the other two fingers, both of which preferably flank the one finger, extend forwardly, preferably in the same plane, to form a gasket retaining clip. In this embodiment, there is no need to separately form and attach one of the alignment guides to the gasket frame. Alternatively, a portion of the frame adjacent an edge of the opening may extend rearwardly to define an alignment guide and then extend back upon itself to extend forwardly of the gasket frame and define a gasket retaining clip.

In yet another embodiment, the gasket assembly is provided with a series of slotted strips that are formed to define flexible conductive fingers. The strips are attached to sides of the shielding cage at an angle and in opposition to the opposing sides of the bezel. In this manner, the gasket is pressed against the bezel by the cage, rather than the bracket.

These and other aspects, features and advantages will be clearly understood through a consideration of the following detailed description.

### BRIEF DESCRIPTION OF THE DRAWINGS

During the course of the following detailed description, reference will be made frequently to the following drawings in which like reference numbers identify like parts and in which:

FIG. 1A is a perspective view of an angled shielding cage of a gasket assembly;

FIG. 1B is the same view as FIG. 1A but with the bezel, or faceplate exploded therefrom;

FIG. 1C is the same view as FIG. 1B, but with the EMI gasket removed from the gasket frame for clarity;

FIG. 1D is the same view as FIG. 1C but with the gasket frame and one guide member thereof removed for clarity;

FIG. 1E is the same view as FIG. 1B, but taken from underneath;

FIG. 2A is a perspective view similar to FIG. 1A but taken from the opposite direction and the bezel, frame and gasket sectioned horizontally for clarity;

FIG. 2B is a perspective view similar to FIG. 1C but taken from the opposite direction thereof illustrating the contact made between the shielding cage and the gasket frame;

FIG. 3 is a top plan view of a shielding cage and angled EMI gasket assembly;

FIG. 4A is a perspective view of the gasket assembly, with the shielding cage initially, but not fully inserted into the gasket frame opening for purposes of illustration, and with the circuit board removed and taken from the right side thereof;

FIG. 4B is the same as FIG. 4A but with the bezel removed and the gasket exploded away from the gasket frame; and the shielding cage partially inserted into the frame opening;

FIG. 5A is a perspective view of the gasket frame used in the assembly of FIG. 1A;

FIG. 5B is a top plan view of the gasket frame of FIG. 5A;

FIG. 6A is a perspective view of an alternate embodiment of a gasket frame for use in gasket frame assemblies of the Present Disclosure;

FIG. 6B is a top plan view of the gasket frame of FIG. 6A;

FIG. 6C is a front elevational view of the gasket frame of FIG. 6A;

FIG. 6D is a top perspective view of the gasket frame of FIG. 6A installed over a shielding cage;

FIG. 6E is the same view as FIG. 6D but with the conductive gasket in place upon the gasket frame;

FIG. 7A is a perspective view of another alternate embodiment of an angled gasket assembly utilizing spring fingers mounted to the exterior of the shielding cage;

FIG. 7B is the same view of FIG. 7A but with the spring finger gasket strips exploded away for clarity;

FIG. 8 is a top plan view of FIG. 1A, sectioned horizontally along line 8-8 thereof to better illustrate the contort of the gasket with the gasket frame and bezel;

FIG. 9A is a perspective view, taken from below of the front end of the gasket assembly of FIG. 1A, illustrating the extension of the shielding cage through the gasket frame opening and the clearance between the shielding cage and the gasket retaining clips;

FIG. 9B is the same view as FIG. 9A, but taken from above, with a portion of the gasket removed to show the left gasket-retaining clip; and,

FIG. 9C is an elevational view of the gasket assembly of FIG. 2A, without the sectioning thereof and taken from the right side thereof at the level of the printed circuit board.

### DETAILED DESCRIPTION OF THE PREFERRED EMBODIMENTS

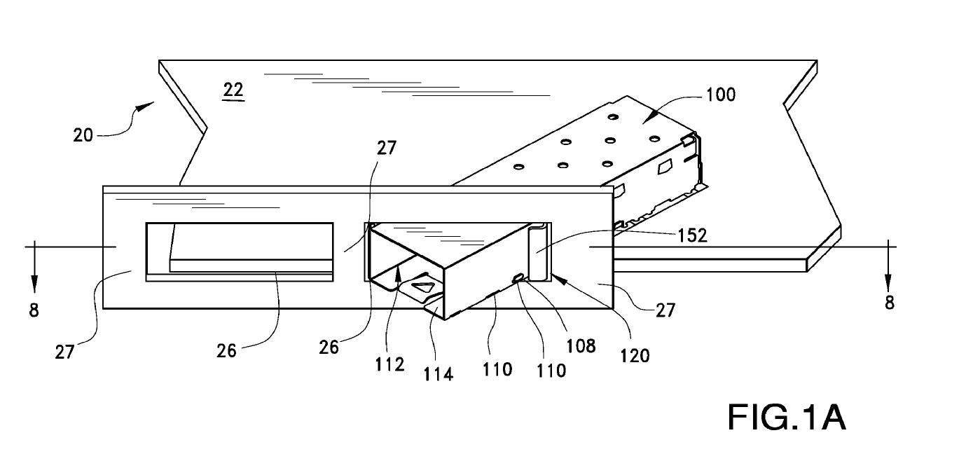

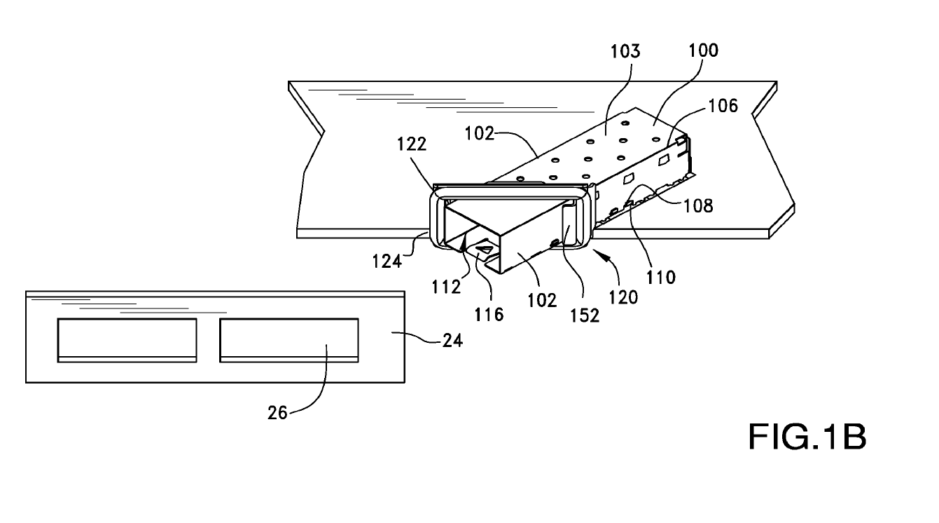

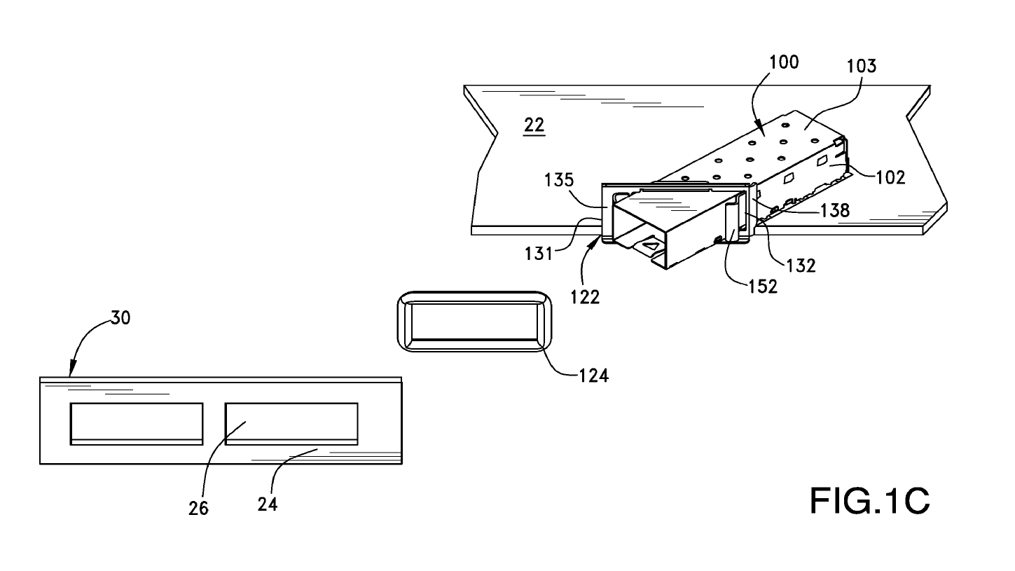

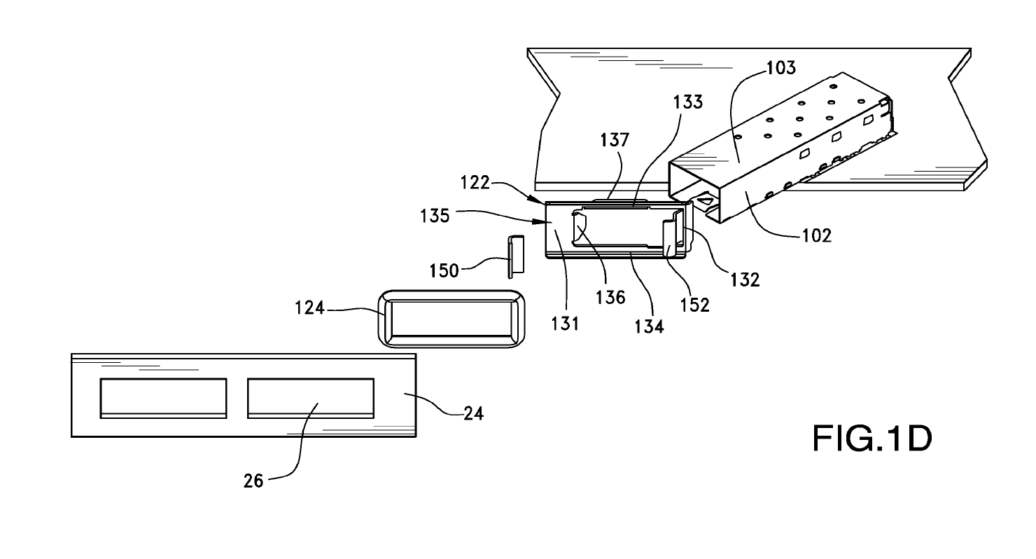

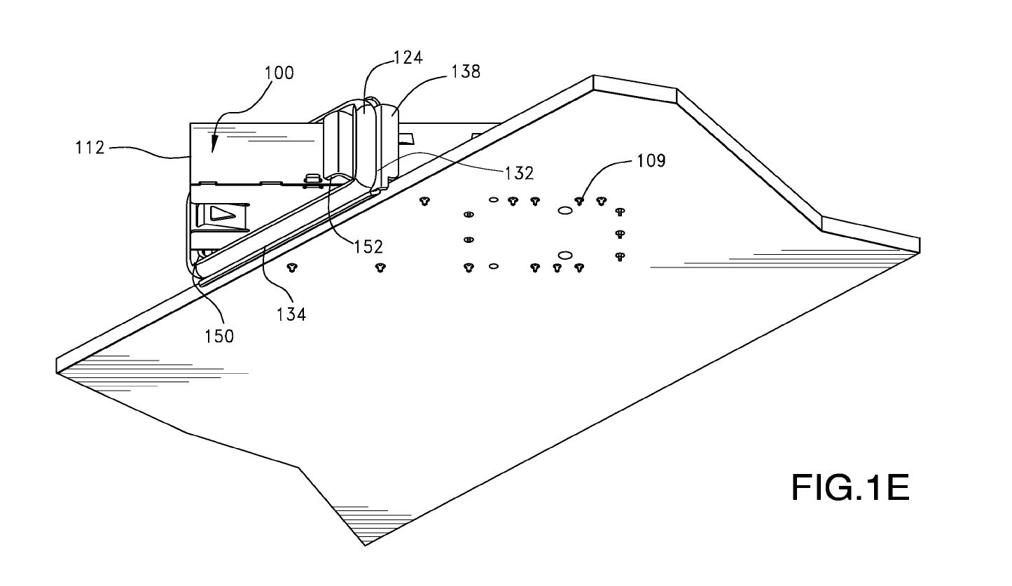

FIG. 1 illustrates one embodiment of an angled shielding gasket assembly we have developed, in its common environmental setting, namely, that of an electronic device 20, such as a server or router, which includes an internal printed circuit board 22. A faceplate, or bezel 24, extends along a face of the device 20 and includes singular openings 26 as shown that are spaced apart from each other and which are separated by intervening posts 27. Internal connectors (not shown) are mounted on the circuit board 22 in proximity to the bezel openings 26 and these connectors typically are engaged by electronic modules that are inserted through openings in the bezel 24 into engagement with the board mounted connector.

In order to reduce the emission of electromagnetic interference (“EMI”), conductive cages 100 are typically provided that have a hollow interior. The cages 100 fit over the connectors and have specific length to accommodate the modules. As such, the cages 100 have a plurality of walls, namely two sidewalls 102, one top wall 103 and a bottom wall 104 that are interconnected together by way of bends 106, or retaining tabs 108, that are received in sidewall slots 110, to form a hollow four-sided conductive member with an opening 112 at its front face 114. One of the walls, shown as the bottom wall 104, may include an engagement tab 116 for engaging a module inserted into the cage 100. The shielding cage 100 has a plurality of mounting legs depending downwardly from its side walls 102 and may take the form of compliant pin mounting loop 109 that are received in vias 23 formed in the circuit board 22.

EMI shielding is not only desired around the internal module-connector connection, but also at the bezel opening 26. Conductive gaskets are used to prevent such emissions, and in the past designers using angled cages have had to rely upon expensive die-cast gasket members or the use of custom printed circuit boards, both of which are expensive. An EMI shield should have a plurality of contact points between it and the structure which it shields, leading to ground. The gasket assembly shown and described herein provides a reliable and inexpensive solution to such a problem.

FIG. 1B illustrates a gasket assembly 120 that includes a conductive, preferably metal, gasket frame 122 that supports a flexible or compressible conductive gasket 124 in a path around both the shielding cage 100 and the bezel opening 26, as well as the frame 122. The frame 122 holds the gasket 124 in place so that it may be pressed against the rear face 30 of the bezel 24 and the front face 135 of the gasket frame 122 when the bezel 24 is assembled onto the device. The bezel 24 is grounded to the chassis of the electronic device 20. The gasket assembly 120 has a plurality of contact points between it, the shielding cage 100 and the bezel 24 so as to form a plurality of ground paths such that EMI impinging thereupon is effectively directed to ground.

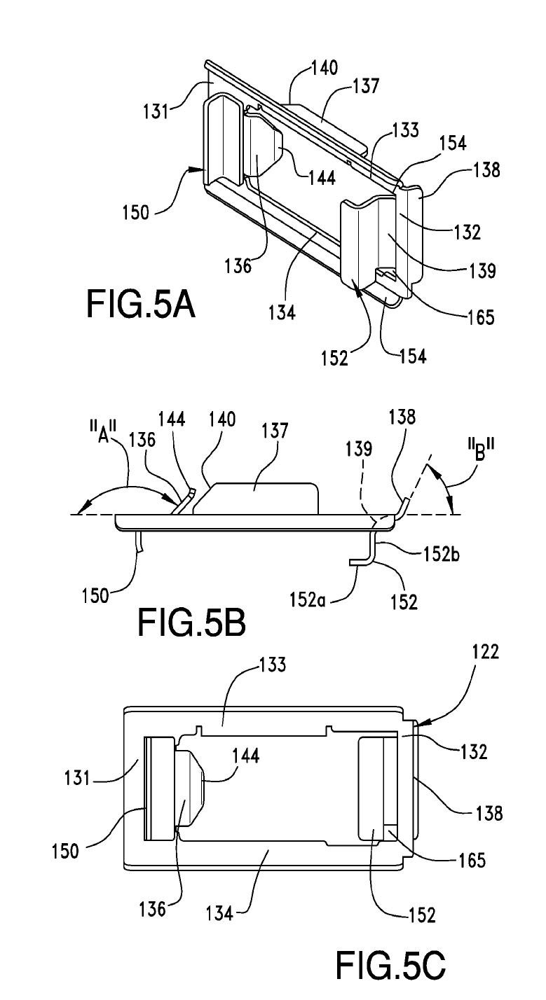

A first embodiment of the gasket assembly is shown best in FIGS. 1D, 2B and 5A. Specifically, in FIG. 5A it can be seen that the frame 122 has a generally rectangular configuration with an interior, or central, opening 130 that is defined by a plurality of interconnected walls, including two sidewalls 131, 132, top wall 133 and bottom wall 134. The gasket frame 122 may be conveniently formed of sheet metal, although it could be assembled by way of a casting or assembly of individual pieces attached to each other but stamping and forming it out of sheet metal presents economic and cost advantages. The opening 130 of the gasket frame 122 is sized to receive the shielding cage 100 at an angle thereto and preferably contacts the shielding cage 100 on at least three of its four walls.

The frame 122 may be considered as having a front face 135 that faces the rear face of the bezel 24 and a rear face that faces the opposite direction, generally toward the rear of the shielding cage 100. In order to orient the shielding cage 100 correctly within the gasket frame 122 at least two of the frame walls 131, 133 have alignment members associated therewith, and in the embodiment illustrated, three of the frame walls have three separate alignment members. Where two such alignment members are utilized, it is preferred that they are disposed on one sidewall and the adjacent top wall so that the longitudinal axes thereof intersect to thereby define a corner that engages the shielding cage in two different directions to orient it at a preselected angle within the gasket frame 122.

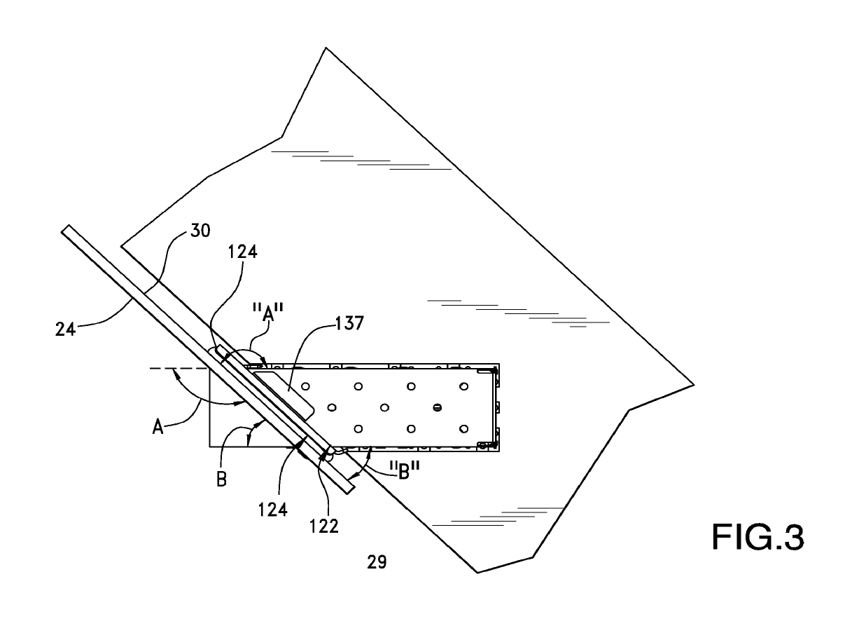

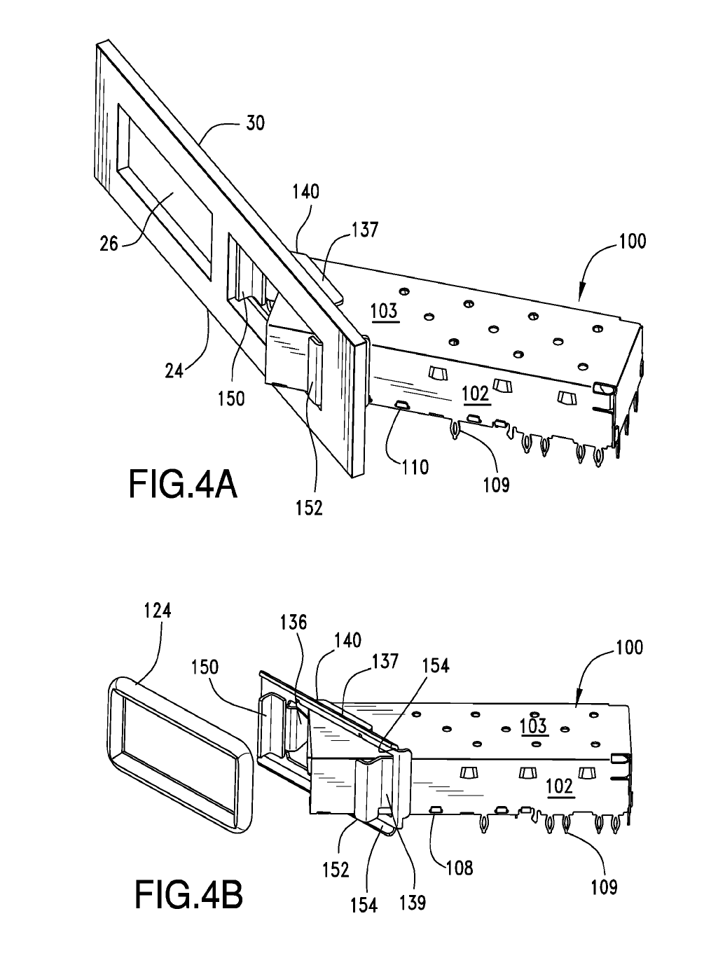

The angular relationship can be understood by reference to the drawings and particularly FIG. 3 thereof. As used herein, “preselected angle” means an angle that is non-orthogonal, i.e. a non-right angle as would occur if the shielding cages 100 of the device 20 were oriented in a straight-on orientation, namely perpendicular to a front edge 29 of the circuit board 22. Rather, the shielding cage 100, as illustrated in FIG. 3, is mounted on the circuit board 22 at either an obtuse angle “A” that extends between the back of the bezel and the left side or edge of the shielding cage 100 or at an acute angle “B” that extends between the back of the bezel and the right side of the shielding cage 100.

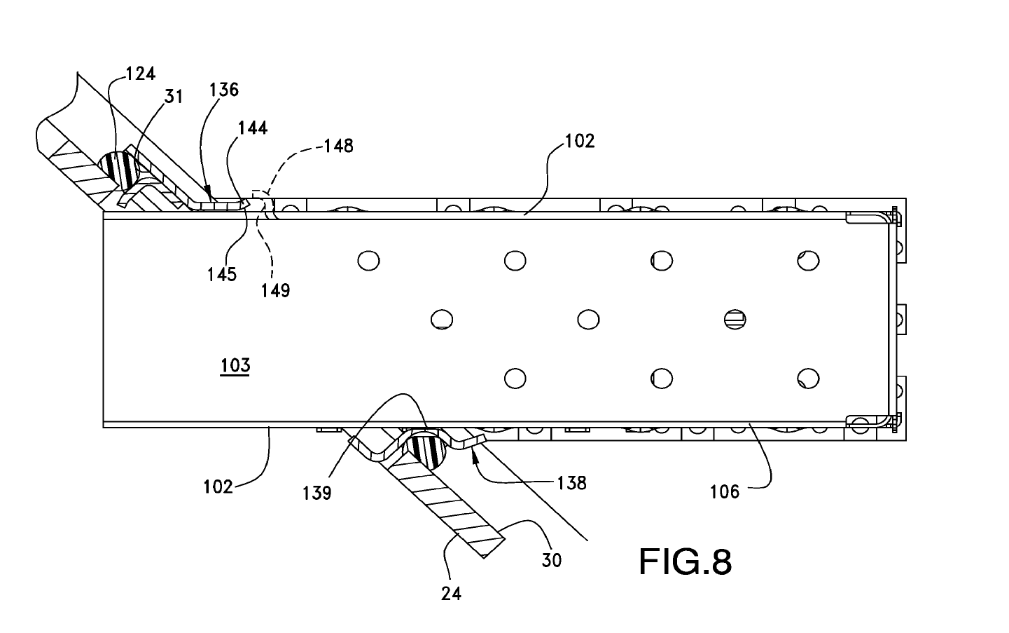

The alignment members act as guides 136, 137 and 139 to orient the shielding cage 100 at a desired preselected angle (angles “A” and “B”) within the opening 130 of the gasket frame 122. In this regard, two of the guides 136, 139 are preferably disposed on opposite sides of the frame opening 130 and at least one of them 136, extends rearwardly (toward the rear end of the shielding cage and away from the rear face) of the bezel 24. It is preferred that these two guides 136, 139 are arranged parallel to each other. In order to maintain them as parallel, the guides 136, 139 are oriented to match the selected angle of the shielding cage 100. In this manner, and as illustrated in FIG. 8, the sidewalls 102 of the shielding cage 100 can contact the guides to maintain the desired angular orientation. It should be noted that the rightmost alignment guide 139 includes an extension 138 that extends rearwardly of it that serves as a strengthening flange. Electrical grounding contact is made between the gasket frame 122 and the shielding cage 100 by at least the three guides contacting opposing walls of the shielding cage and then also to the bezel by way of the gasket 124.

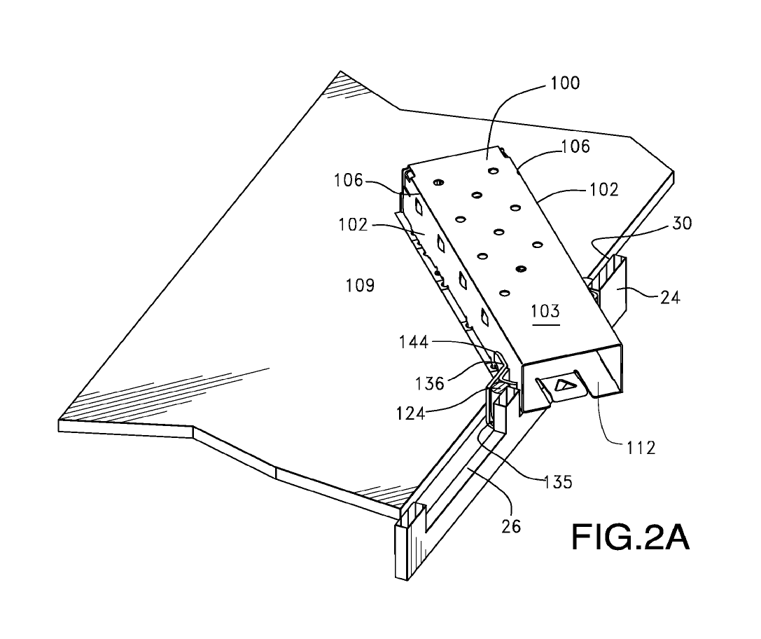

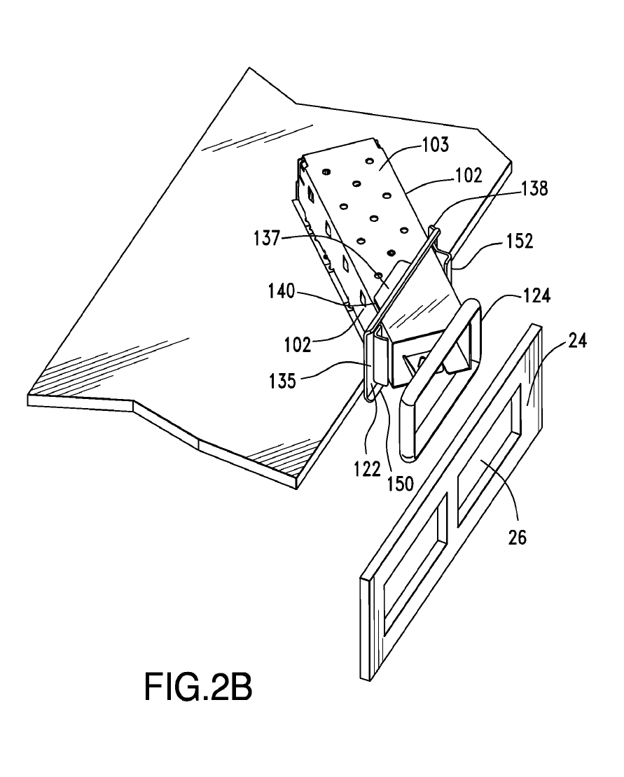

A third guide 137 is shown as provided on the top wall 133 of the gasket frame 122 that is adjacent to the two sidewalls 131, 132 of the frame. This alignment guide 137 takes the form of a flat flange that also extends rearwardly from the gasket frame 122. The alignment guide 137 is preferably flat so that it can contact the top wall 103 of the shielding cage 100 and also has an angled edge 140 that is nearest the left alignment guide 136. This angled edge 140 may assist an assembler in aligning the shielding cage 100 and the gasket frame 132 as shown in FIGS. 2B and 3 where the edge 140 is aligned with the bend 106, or edge of the shielding cage 100 that defines the junction between the top wall 104 and lets side wall 102 of the shielding cage 100. In this manner, the shielding cage may be inserted into the gasket frame opening and aligned along this edge 140 until the shielding cage sidewalls 102 contacts the left guide 136, at the desired angle of application to the circuit board. Accordingly, at a minimum, the first and third guides 136, 137 provide surfaces against which the shielding cage 100 may abut in two different, intersecting axes, e.g., the third (top) guide 137 locates the cage 100 in a horizontal plane, while the first guide 136 locates the shielding cage 100 in a vertical plane.

The gasket frame assembly may be assembled separately onto the shielding cage 100 after it is mounted to the circuit board 22. Or, in most applications, the gasket frame assembly may be attached to the shielding cage 100 and the cage subsequently mounted to circuit board 22. In order to facilitate assembly, the leftmost alignment guide 136 may include a lead-in section 144 that is slightly bent outwardly to prevent stubbing of the cage 100 on the face end of the alignment guide 136, as shown bent in FIG. 8. This lead-in also defines a small cavity 145 between the cage side wall 102 and the alignment guide 136 for solder collection or as a welding location, during attachment of the gasket frame 122 to the shielding cage 100. In an alternative construction, the cage side wall 102 may be lanced, or punched as at 148 (FIG. 8) to form a pocket, or slot, 149 into which the free end of the alignment guide 136 may fit.

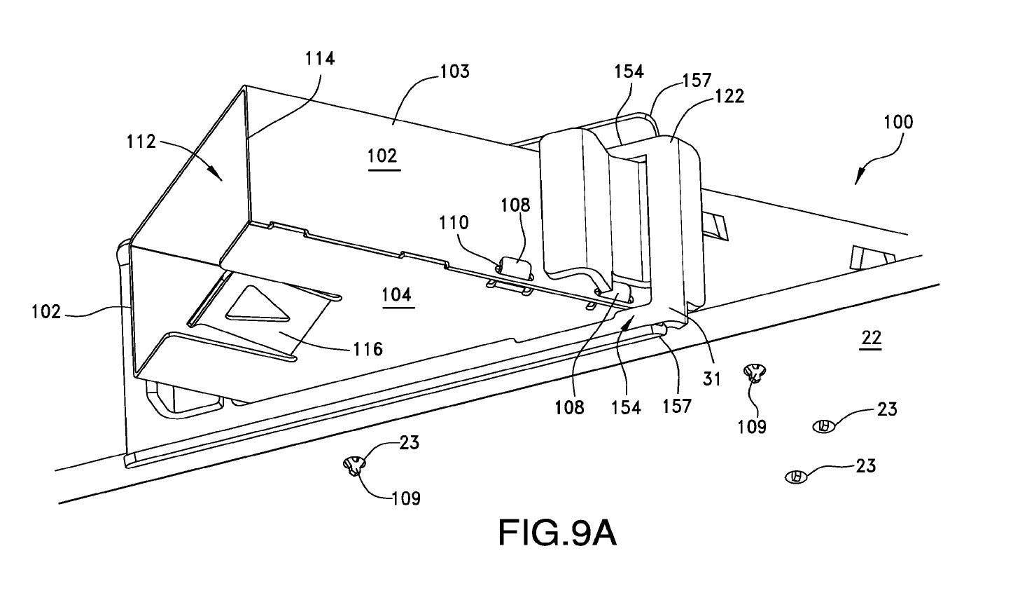

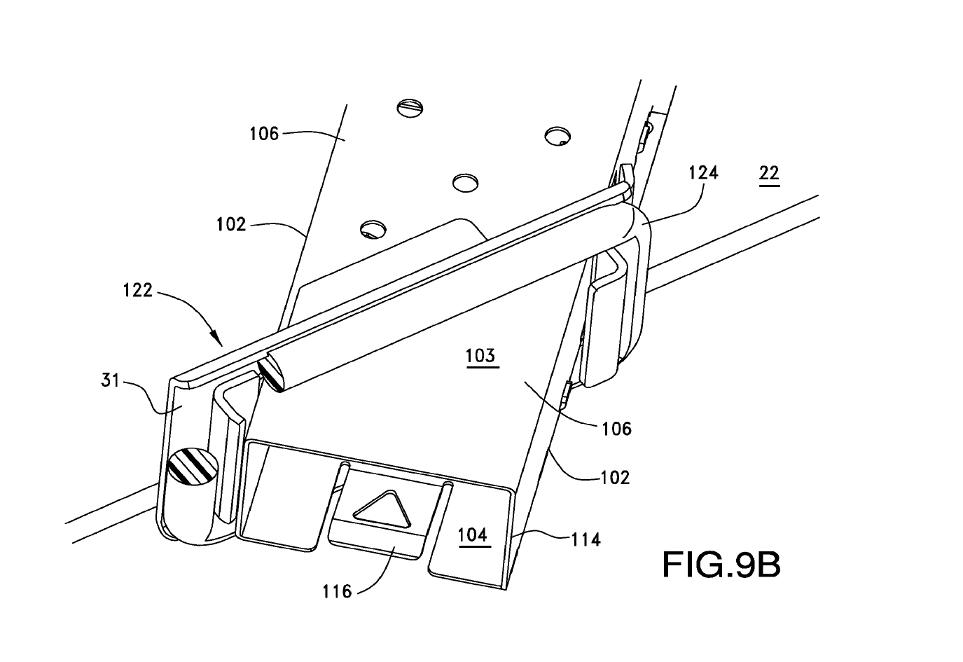

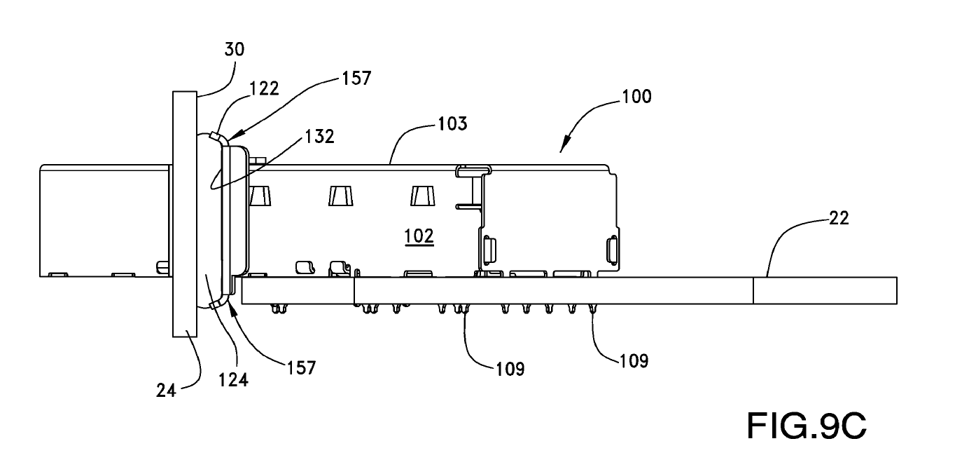

The front face of the gasket frame 122 has a plurality of second members associated therewith which extend forwardly therefrom to define gasket-retaining clips 150, 152, as shown in FIGS. 1D and 5A. The leftmost gasket-retaining clip 150 may be formed separately as an L-shaped member in this embodiment, and attached to the gasket frame 122 such as by welding, while the rightmost clip 152 is preferably formed as part of the gasket frame 122 and as shown it is bent forwardly out of the plane of the frame sidewall 132. This clip 152 is also L-shaped, but is inverted in its orientation with respect to the left gasket-retaining clip 150, as shown best in FIG. 5A. It is desirable, but not mandatory that the two clips 100, 152 are parallel to each other. The right clip 152 may be toed slightly outwards to increase its retention of the gasket, but the parallel orientation is preferred. The right gasket-retaining clip 152 has two portions, a front edge portion 152a and a body portion 152b. This body portion 152b may also be formed with a notch 165 (FIGS. 5A, 5C & 9A) where it meets the gasket frame so as to provide clearance with any shielding cage assembly tabs 108 in its vicinity, as illustrated best in FIG. 9A.

These two gasket retaining clips 150, 152 support a flexible conductive gasket 124. Preferably, the gasket 124 is formed from a compressible and elastic material that permits it to be applied to the gasket-retaining clips and maintain a certain amount of tension when applied thereto to assist in its retention on the gasket frame. The gasket 124 is illustrated as having a circular cross-section, but other configurations, such as rectangular, oblong or the like will be suitable. The gasket 124 may itself be coated with a conductive material or it may be molded or die-cut from an elastic, compressible material, such as an elastomer or elastomeric compound, for example, with conductive material formed as part thereof and in other ways known in the art.

The gasket 124 is best shown in FIG. 9B as having a continuous ring shape that preferably has a length that approximates the perimeter of the gasket frame central opening 130, although the gasket length may be shorter or longer than the perimeter for desired purposes. In this regard, the top and bottom walls 133, 134 of the preselected gasket frame 122 may there respective edges rolled on a radius 157 forwardly to define two, spaced-apart gasket-receiving channels 154 in which the top and bottom extents of the gasket 124 extend around the gasket frame opening 130. (FIG. 9C.) In this manner, the gasket frame 122 and the clips 150, 152 cooperate to retain the gasket in place. Although the left clip 150 is depicted in the Figures as a separate structural element that is attached to the gasket frame 122, it will be understood that the left clip 150 may be formed integrally with the gasket frame 122. Such a construction would necessitate stamping a suitable configuration for the clip in the area of the opening, bending the material rearwardly first to from the left guide of the frame and then folding it back upon itself to project through the opening forwardly of the gasket frame to define the left clip 150. Alternately, the material could be bent forwardly first to form the clip and then back upon itself, rearwardly, to form the guide.

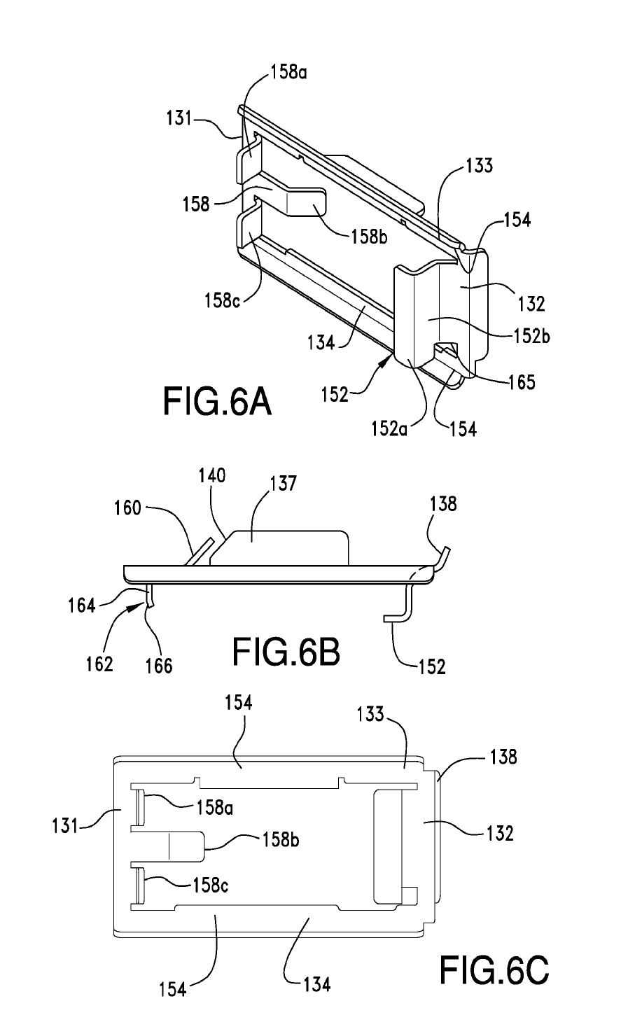

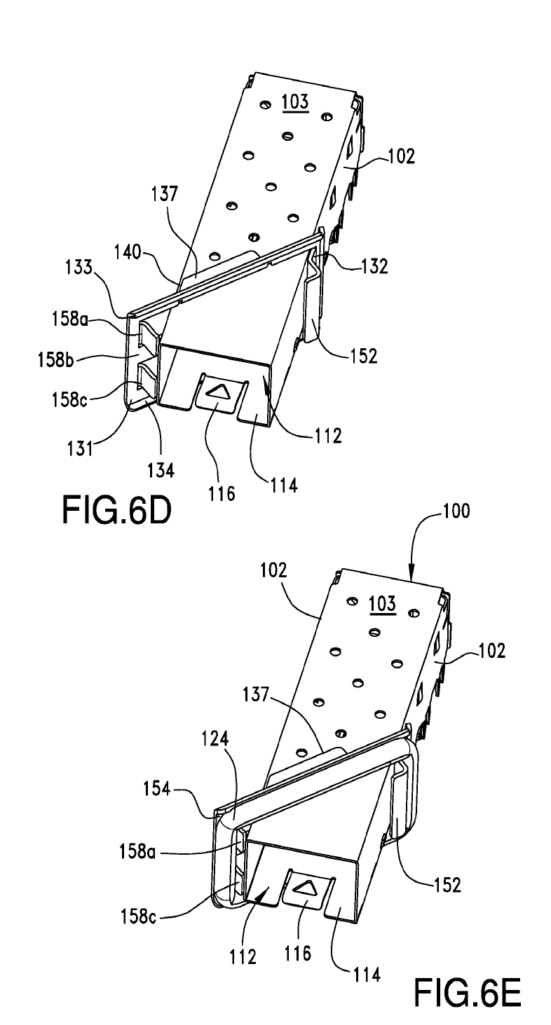

FIGS. 6A-6E illustrate another manner of forming a combined guide-clip member with the gasket frame 122. In this embodiment and as shown in FIG. 6A, the gasket frame 122 is stamped to form guide-clip member 158 that includes a plurality of elongated members, shown as elongated fingers 158a-c that are separated from each other by slots 159, with three such fingers being shown, spaced vertically apart along the sidewall 131 of the gasket frame 122. One of the fingers 158b extends rearwardly at an angle and has a flat free end 160 that contacts the right sidewall 102 of the shielding cage 100. The two fingers 158a, 158c flank the middle finger 158b and extends forwardly of the gasket frame front face to cooperatively define a leftmost gasket-retaining clip 162 that has a projection portion 164 that is preferably parallel to the right gasket retaining clip portion 152. In order to facilitate insertion of the assembly and cage into the bezel opening, the free ends 166 of the two clip fingers 158a, 158c may be bent at an angle to the right to form a lead-in surface that will not catch or otherwise interfere with the bezel opening.

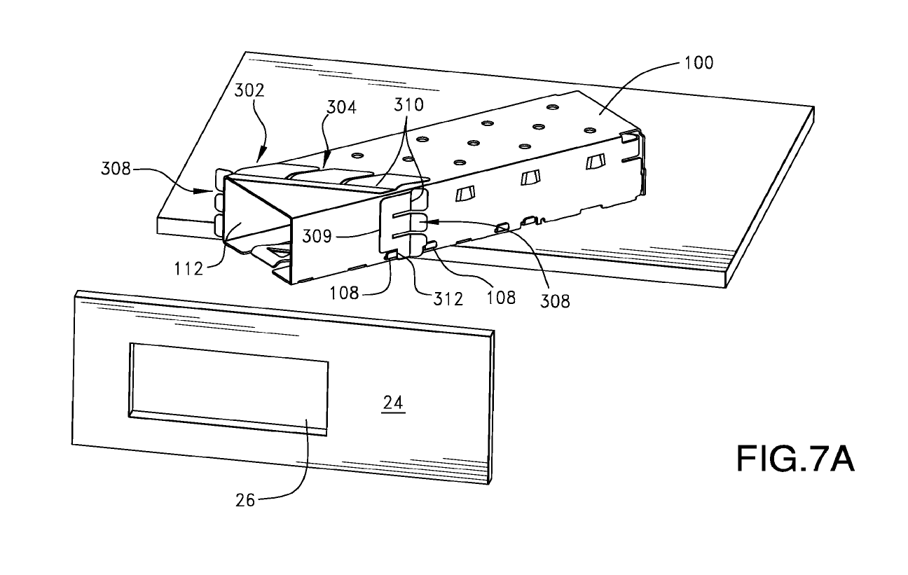

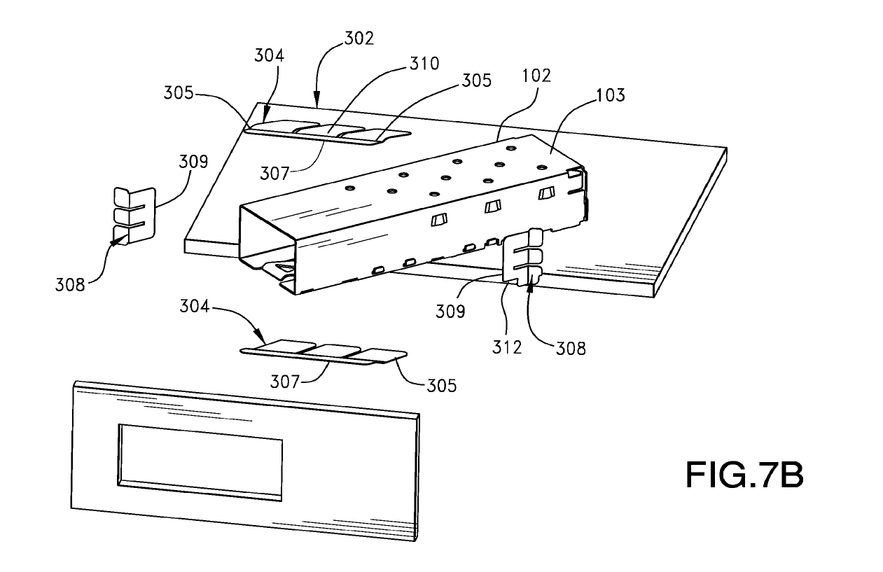

Another embodiment of an EMI gasket assembly 300 of this disclosure is illustrated in FIGS. 7A and 7B. In this embodiment, the gasket 302 is disposed along the exterior of the shielding cage 100 at an angle thereon as shown along a path where the shielding cage 100 and circuit board intersect, which is parallel to the rear face of the bezel. The gasket 302 utilizes two pairs of slotted gasket strips 304, 308 with the top and bottom strip 304 extending at an angle along their supporting top and bottom walls of the shielding cage 100. Similarly, a pair of strips 308 extend vertically on both sides of the cage 100. The top and bottom strips 304 are provided with angled alignment edges 305 at their opposing ends and serve to properly align the strips 304 on the shielding cage 100 at the desired, preselected angle. Such alignment preferably occurs along the edges 106 of the shielding cage 100, in a similar fashion to the manner in which the angled edge 140 of the third alignment guide of the prior embodiments is aligned. Additionally, each of the top and bottom strips 304 have a leading edge 307, which is used as a guide to properly position the side, vertical gasket strips 308 so that the leading edges 307 of the top and bottom gasket strips 304 are aligned with the leading edges 309 of the side, vertical gasket strips 308.

The gasket strips 304, 308 are slotted to define a plurality of elongated members in the form of fingers that extend rearwardly with respect to the front opening of the shielding cage. In order to facilitate insertion of the assembly into the bezel opening, these fingers may be formed in a manner to define a raised contact edge, or stop surface, 310 that will abuts the rear face of the bezel 24 when the bezel is correctly attached to the electronic device in which the shielding cages are used. With such a structure, the gasket strips may be notched in a manner similar to the gasket frame embodiments of FIGS. 5A & 6A, in order to avoid interference with the shielding cage assembly tabs 108. This is illustrated best in FIG. 7A where the right gasket strip 308 has a notch 312 formed along its leading edge 309

Preferred embodiments of the Present Disclosure are described herein, including the best mode known to the inventors for carrying out the Present Disclosure. Variations of those preferred embodiments may become apparent to those of ordinary skill in the art upon reading the foregoing description. The inventors expect skilled artisans to employ such variations as appropriate, and the inventors intend for the Present Disclosure to be practiced otherwise than as specifically described herein. Accordingly, the Present Disclosure includes all modifications and equivalents of the subject matter recited in the claims appended hereto as permitted by applicable law. Moreover, any combination of the above-described elements in all possible variations thereof is encompassed by the Present Disclosure unless otherwise indicated herein or otherwise clearly contradicted by context.

What is claimed is:

1. An electromagnetic interference (“EMI”) gasket assembly for use with a shielding cage that is mounted to a circuit board in a device that has a face plate, the face plate having opposing front and rear sides and an opening through which a portion of the shielding cage fits, comprising:
a frame member, the frame member having a plurality of sidewalls that cooperatively define a central opening therein, the opening being sized to receive a portion of the shielding cage therein, said frame member including at least one alignment guide for orienting said frame on said shielding cage at a preselected, non-orthogonal angular orientation to said frame; and
a flexible conductive gasket extending around the frame central opening along the frame front side so as to contact the face plate rear side when said frame is assembled in the device.

2. The EMI gasket assembly of claim 1, wherein said frame member further includes at least two gasket-retaining clips extending forwardly from the frame front face.

3. The EMI gasket assembly of claim 2, wherein the gasket-retaining clips are generally L-shaped and are aligned with each other on opposite sides of the frame member opening.

4. The EMI gasket assembly of claim 3, wherein said gasket-retaining clips extend vertically along said frame member and are inverted with respect to each other.

5. The EMI gasket assembly of claim 1, further including at least two alignment guides, one of the two alignment guides extending rearwardly from said frame member.

6. The EMI gasket assembly of claim 5, wherein said two alignment guides are disposed on opposite sides of said frame member opening.

7. The EMI gasket assembly of claim 5, wherein said two guides are disposed on adjacent sides of said frame member opening.

8. The EMI gasket assembly of claim 5, wherein one of said two alignment guides has an angled edge for orienting said frame member on said shielding cage at said preselected, non-orthogonal angular orientation by aligning with a side edge of said shielding cage.

9. The EMI gasket assembly of claim 2, wherein said two gasket-retaining clips are disposed on opposite sides of said frame member opening and are formed integrally with said frame member.

10. The EMI gasket assembly of claim 2, wherein said frame member includes a plurality of elongated fingers formed proximate to one side of said frame member opening, at least one of the fingers extending rearwardly from said frame member to define one of said alignment guides thereof and at least another of said fingers extending forwardly from said frame member to define one of said gasket-retaining clips.

11. The EMI gasket assembly of claim 5, wherein said two alignment guides extend along said gasket frame at approximately the same angle.

12. The EMI gasket assembly of claim 11, further including a third alignment guide extending rearwardly from said frame member, said two alignment guides extending vertically on opposite sides of said frame member opening and the third alignment guide extending horizontally alongside of said frame member opening adjacent to said two alignment guides.

13. The EMI gasket assembly of claim 2, wherein said gasket-retaining clips and said gasket frame front face cooperatively define portions of a gasket-receiving channel extending around said frame member opening.

14. The EMI gasket assembly of claim 1, including a conductive cage at least partially received in said frame member opening, the cage abutting at least one of said alignment guides and being oriented at a preselected non-orthogonal angle to said frame member.

15. A shielding cage assembly for receiving an electronic module through an opening of a bezel of an electronic device, the cage, comprising:
an elongated, conductive cage member having a hollow interior defined by a plurality of walls;
a frame member having a central opening for receiving a portion of the cage member therein at a preselected, non-orthogonal angle to the frame member, said frame member including a plurality of alignment guides extending from one face of said frame member and into contact with said cage member walls, the alignment guides orienting said cage member within said frame member at the preselected non-orthogonal angle, and a plurality of gasket-retaining clips extending from an opposite face of said frame member; and
a conductive gasket supported by the gasket-retaining clips in a path extending around said frame member opening.

16. The angled shielding cage assembly of claim 15, wherein one of the alignment guides extends rearwardly of said frame member, and at least two gasket-retaining clips extend forwardly of said frame member, the two gasket-retaining clips being disposed on opposite sides of the central opening.

17. The angled shielding cage assembly of claim 16, further including a plurality of elongated fingers that cooperatively define one of said alignment guides and gasket-retaining clips.

18. The angled shielding cage assembly of claim 16, wherein two of said alignment guides are disposed on adjacent sides of said gasket frame opening.

19. The angled shielding cage assembly of claim 15, wherein opposing edges of said gasket frame are formed at a radius to define, in cooperation with said gasket-retaining clips, channels that receive portions of the conductive gasket therein.

20. The angled shielding cage assembly of claim 15, wherein one of said gasket-retaining clips has a notch formed therein, the notch providing clearance for a cage assembly tab when said cage member is received within said frame member.

21. An EMI gasket assembly for use on a shielding cage, the shielding cage including four cage walls, the gasket assembly comprising:
a gasket frame including two sidewalls, a top wall and a bottom wall, the gasket frame including an opening disposed therein dimensioned to received a portion of said shielding cage therein, said gasket frame including at least two guides disposed thereon adjacent said opening, one of the two guides extending in a first direction from said frame at a preselected, non-orthogonal angle thereto for contacting said cage when said cage is inserted into said opening and for orienting said cage at the preselected, non-orthogonal angle to said frame, said guides including an alignment edge along which said shielding cage may be oriented; and
a conductive gasket and said frame including a pair of gasket-retaining clips for holding the gasket in place around said opening, the gasket-retaining clips extending in a second direction different than the first direction, said gasket-retaining clips being disposed on opposite sides of said frame opening.

22. The gasket assembly of claim 21, further including a third guide, the three guides being disposed along adjacent sides of said frame opening.

23. The gasket assembly of claim 21, wherein one of said gasket-retaining clips includes a notch disposed in an edge thereof for providing clearance to an assembly tab of said shielding cage.

24. An EMI gasket assembly for use on a shielding cage, the shielding cage including four cage walls and being mounted to a circuit board at a non-orthogonal angle, the gasket assembly comprising:
a plurality of slotted EMI gasket strips, the gasket strips being arranged in two pairs of gasket strips, a first pair of said gasket strips being attached to said shielding cage sidewalls in a vertical orientation and a second pair of said gasket strips being attached to said shielding cage in a horizontal orientation, the second pair of gasket strips including angled edges at opposing ends of said gasket strips for orienting said gasket strips on said shielding cage at a preselected non-orthogonal angle.

25. The EMI gasket assembly of claim 24, wherein said gasket strips include raised portions forming a contact edge on each of said gasket strips for contacting the opening of a bezel.
